(19) United States
(12) Patent Application Publication
(10) Pub. No.: US 2005/0134945 A1
(43) Pub. Date: Jun. 23, 2005

(54) 3D view for digital photograph management

(75) Inventor: Matthew William Gallagher, Chatswood (AU)

Correspondence Address: FITZPATRICK CELLA HARPER & SCINTO, 30 ROCKEFELLER PLAZA, NEW YORK, NY, 10112, US

(73) Assignee: CANON INFORMATION SYSTEMS RESEARCH AUSTRALIA PTY. LTD., NORTH RYDE NEW SOUTH WALES (AU)

(21) Appl. No.: 11/013,364

(22) Filed: Dec. 17, 2004

(30) Foreign Application Priority Data
Dec. 17, 2003 (AU) 2003907006

(51) Int. Cl. G06K 9/00; G03F 3/10

(52) U.S. Cl. 358/527; 382/154

(57) ABSTRACT

A method is disclosed for viewing a collection of data objects. The method initially sorts the collection according to at least two fields associated with the data objects. The data objects are then arranged within a range along said at least two fields into groups. A three dimensional presentation of the collection is then formed having two of the dimensions formed by two of the at least two fields and a third dimension incorporating a representation of each data object in the corresponding group.

### CROSS-REFERENCE TO RELATED PATENT APPLICATIONS

This application claims the right of priority under 35 U.S.C. § 119 based on Australian Patent Application No. 2003907006, filed 17 Dec. 2003, which is incorporated by reference herein in its entirety as if fully set forth herein.

### FIELD OF THE INVENTION

The present invention relates to computer graphical user-interfaces and, in particular, to user-interfaces for digital photograph and video management applications.

### BACKGROUND

The first affordable digital cameras, having a relatively high resolution in the megapixel range, became available in the mid-to-late 1990's. Since that time, a large range of software has been developed to support digital photography, this being operable on desktop or portable computers for home or office purposes.

For digital photograph collections larger than a few dozen photographs, the most important task is arguably management of the collection. Such management will involve providing quick access to any photograph within the collection and the dispatch of photographs to other programs or various tasks for viewing, editing, printing, and the like.

In terms of accessing photographs, two major metaphors are employed. The first involves file-system views, which involve arranging the photographs by the position of their file on the hard-drive of the user's computer by which the photographs are stored. The second involves meta-data based views, where the collection may be sorted based on the attributes of the photograph, like date or keywords, that the user has applied to the photograph. In many ways these two metaphors are interchangeable.

By far the most common way of managing a photograph collection is simply through the file-system. Users save their photographs from their camera or other source to a directory on a computer hard-drive. From there, the user can take advantage of file management capabilities of the operating system associated with the computer to view the files. This is typically performed by opening the files with a program for viewing or editing. The file-system also allows the files to be categorised into directories and sorted by name or date. Operating systems such as Mac™ OS X, Windows™ XP and KDE™ often tout their strengths in this type of, largely file-based, simple photograph management.

Many dedicated photograph management programs emulate this style. This type of program keeps the directory structure and shows the files in their directories but offers more sophisticated camera integration, thumbnail viewing, dispatch to photograph editing or printing programs, or meta-data editing, than provided by the operating system. Programs in this category are numerous and include ACDSee™, Canon Zoombrowser™, BetterBrowser™, IMage, PhotoMesa™, Canon ImageBrowser™, and many more.

The variety and style of visual displays that this type of program can generate are limited by the directory structure. Proper display of the user's entire collection by date is difficult because the collection may not all reside in one place. A simple flat two dimensional (2D) view also limits how much visual structure can be created and how many thumbnails can be squeezed into the screen of the computer at one time. With limited visual structure, distinguishing the content of thumbnails becomes essential to navigate the collection. This can limit the utility of collections of thousands of images. However, such a virtual “album”, as defined by the directories in which the photographs reside, are simple, and therefore easy and inexpensive to implement.

The second type of photograph management software is the meta-data sorted type. This type of program typically requires all photographs to be registered with the program. At the time of registration, the photographs are added to a database and various meta-data for the photographs is stored. To navigate the photograph collection, the user selects an attribute, for example date, and the entire collection is sorted by this attribute. Often the sorting provides some form of categorisation. Typically, with the dates example, headings may be provided at the top for years or at the top of photographs taken at the same time. The results are presented as thumbnails of the photographs, arranged in a two dimensional grid.

This second type of photograph management is normally considered the more sophisticated of the two, since file management is generally operated by searches across a database, being a file system. File based management is therefore actually a sub-set of meta-data sorted photograph databases.

Examples of programs which allow digital photograph collections to be navigated based on the meta-data associated with the photographs, rather than the file system locations of the photographs include Adobe Photoshop™ Album, Picasa™ and iPhoto™. These programs can perform searches and order the collection by a range of different criteria, such as date, name, keywords, etc. However these programs are subject to the criticism that they are centred upon the remaining flat two dimensional view which limits the visual structure.

Both the file directory and meta-data sorted approaches to photograph management suffer from the same problem, being that the current view is invariably a grid of photograph thumbnails. While this does offer the most pixels visible for each photograph when displayed on a rectangular two-dimensional display screen, it provides almost no visual structure for the information. Users must visually scrub (move their eyes over) every photograph on screen to track down what they are looking for. There is also no “orientation”, in that every grid of photograph thumbnails looks very similar to every other grid of thumbnails. As such, the user can quickly become lost if their collection is bigger than the 200-300 thumbnail representation of photographs that will comfortably fit on a typical computer display screen.

Another type of image searching is “content-based image retrieval” (CBIR). This is essentially another sophisticated form of meta-data searching, and involves processing each image to identify visual characteristics like the colour of the subject, the number of major lines in the image and the overall texture of the image. A research project described in the paper “An Interactive 3D Visualization for Content-Based Image Retrieval” M. Nakazato, T. S. Huang; Beckman Institute for Advanced Science and Technology, University of Illinois at Urbana-Champaign proposed a system called “3D MARS”. 3D MARS took a database built in this fashion and used common database 3D visualization techniques to display the images placed along three axes depending on these three visual characteristics.

One problem with the 3D MARS research project was that the visual characteristics were hard to calculate and did not always correlate with how users mentally classified their images. The displays of the database also tended to look largely unsorted and scattered because the display had little genuine structure. Consequently, the user was not presented with an easily navigable result. The research project also required immersive navigation involving a first person view that placed the viewer in the middle of the database. This meant that much of the database was occluded, behind the viewer, hidden behind other photographs or otherwise outside the field of view. The result was that the display seemed cluttered and disorganised. Since many photographs were occluded, at any given time, most photographs could not be seen.

Many projects, both commercial and research, have investigated three dimensional (3D) visualisation as a means of better presenting information in databases. The most obvious reason is that it allows results to be plotted along more than two axes—something that is difficult in the two dimensional display environment provided by a computer screen. Some projects though, have explored this type of visualisation simply to offer a different visual metaphor, to be visually distinctive in the marketplace, or take advantage of the features of modern computer graphics cards.

The basic type of 3D visualisation is the immersive virtual-reality environment, where the viewer is placed inside the 3D model. An example of this is a program simply titled 3D-Album™ manufactured by Micro Research Institute, Inc. of the USA. This program takes a collection of photographs and presents them in locations around a 3D environment that can then be navigated by the user or toured along a virtual path. This type of arrangement, whilst fun to use, is of little utilitarian benefit. Information is not sufficiently dense to allow management of dozens, let alone hundreds or thousands of images. The arrangement is also not structured and sufficiently organized to allow rapid location of one image from among a vast number.

Other types of visualization have attempted more utilitarian purposes. A research project at Massachusetts Institute of Technology called the CAES System, constructed 3D models from information in a database. The database contained objects with location data on the MIT campus. Icons representing these objects could then be placed according to their location data on a 3D model of the MIT campus. Co-located items were stacked on top of each other. The researchers on this project ultimately concluded that this form of display was not entirely successful. Placing items on a 3D map in this way did not result in sufficiently dense information. The amount of the 3D map that was required to recognise specific features outweighed the actual result data that was presented. In the CAES system, the campus map did not provide a good means of rapidly associating information with its meaning. Also, since the results were icons representing data, not data with an actual visual component, the visual presentation was a clumsy way of presenting this textual data.

Other efforts at using 3D visualisation to structure and display data include the PARC Cone Tree manufactured by Xerox Corporation, which is really only suited to presenting tree structures and is a questionable improvement on 2D techniques for the same thing. Also, U.S. Pat. No. 5,847,709 granted Dec. 8, 1998 to Card et. al., provided a 3D document workspace divided hierarchically in terms of interaction rates with focus, immediate and tertiary spaces. This arrangement was only really suited to presenting a typical desktop metaphor and had questionable scope for handling large numbers of documents.

An interesting arrangement of visual objects in 3D is found in U.S. Pat. No. 6,005,578 granted Dec. 21, 1999 to Cole where visual objects were presented in laterally connected loops, the loops then being stacked in a vertical direction. This proposal was conceived as a hyper-linked environment more than a representation of search results from a database, and provides little scope for sorting along multiple axes.

A more functional approach to display of information from a database is given in U.S. Pat. No. 5,621,906 granted Apr. 15, 1997 to O'Neill. In this approach, information along at least two axes is presented (date into the distance and time vertically). The axial constraint simplified the structure of the data displayed and also simplified the navigation which is often the worst part about immersive 3D display.

Basic 3D -charts and graphs have often succeeded in presenting data in more than two dimensions. The charting capabilities of Microsoft Excel™ and higher end visualization programs like Amira™ or 3D-Master™ have enjoyed great success in presenting largely numerical data in three dimensions. One of the strengths of these programs is that they list their data within a confined space. The boundary of this space is clearly labelled with axes and all data within the region can be quickly associated with the relevant point along each axis.

### SUMMARY OF THE INVENTION

It is an object of the present invention to substantially over come, or at least ameliorate, one or more deficiencies of prior art arrangements.

In accordance with one aspect of the present invention there is disclosed a method of viewing a database including visual media files, said method comprising the steps of:
(a) sorting said database according to at least two fields associated with said media files;
(b) arranging said media files within a range along said at least two fields into groups;
(c) forming a three dimensional presentation of said database having two of said dimensions formed by two of said at least two fields and a third dimension incorporating a representation of each said media file in the corresponding said group.

Other aspects of the invention are disclosed.

### BRIEF DESCRIPTION OF THE DRAWINGS

At least one embodiment of the present invention will now be described with reference to the drawings, in which:

FIG. 1 illustrates a display screen 3D presentation for an image collection;

FIG. 2A is a schematic block diagram representation of a 3D photograph management system;

FIG. 2B is a functional representation of operation of the system of FIG. 2A;

FIG. 2C depicts a database used in the described arrangement;

FIG. 3 is a flowchart of a method for 3D photograph management;

FIG. 4 is a flowchart of the render process of FIG. 3;

FIG. 5 shows the same collection as FIG. 1 with the cursor over the group at the intersection of “June” and “2000”;

FIG. 6 shows a render frame during animated zooming into June 2000 of FIG. 5;

FIG. 7 shows a single group containing 27 photographs, being the zoomed result of the process depicted in FIG. 6;

FIG. 8 shows a render frame during the animated zooming into a single image from the group of FIG. 7;

FIG. 9 shows the image from FIG. 8 at the end of the animation;

FIG. 10 shows a detailed image of a photograph database GUI organised by month and year; and

FIG. 11 shows the GUI of FIG. 10 after selection of one of the months.

### DETAILED DESCRIPTION INCLUDING BEST MODE

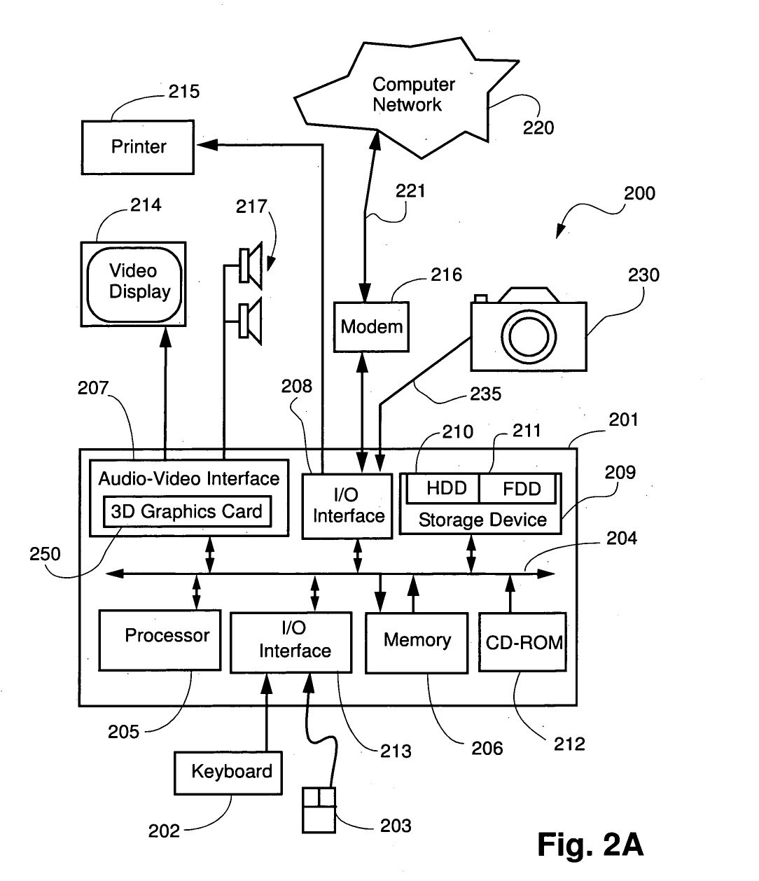

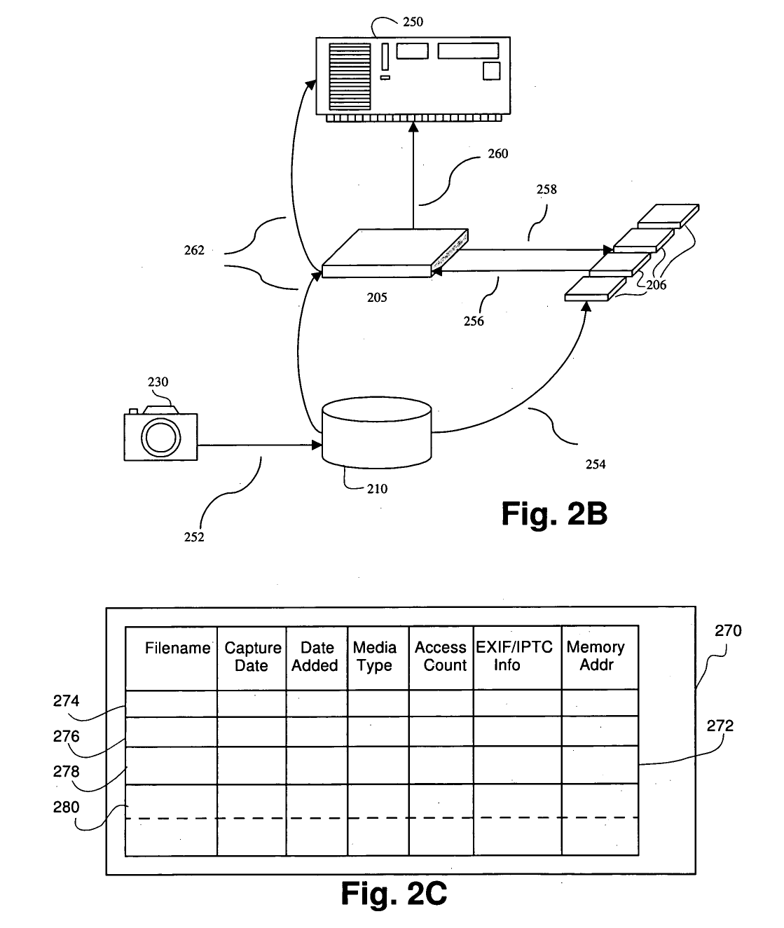

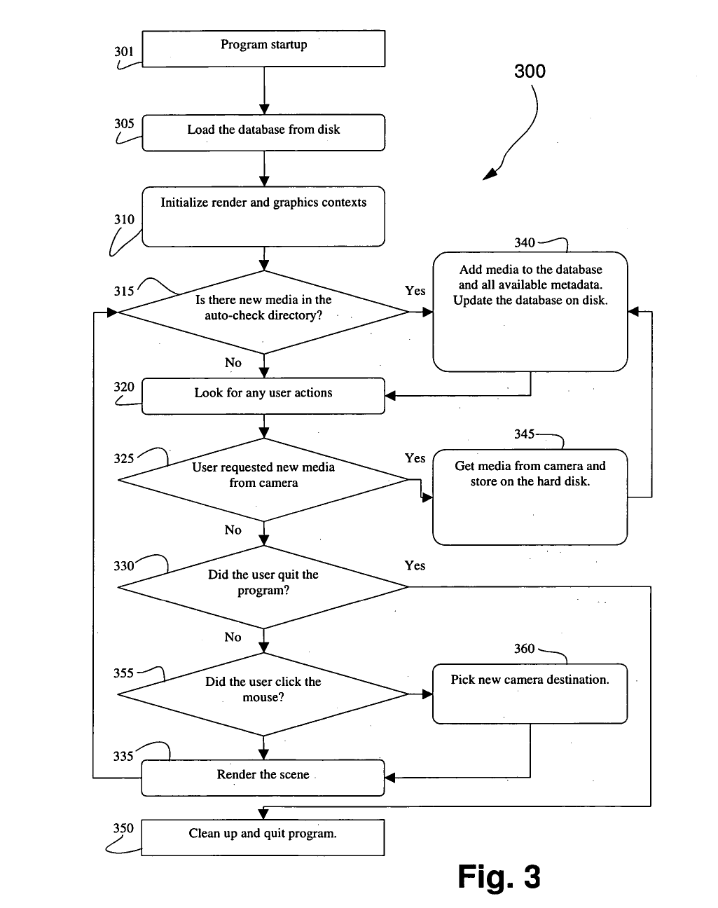

The methods of photographic data management described herein are preferably practiced using a general-purpose computer system 200, such as that shown in FIG. 2 wherein the processes to be described in FIGS. 3 to 9 may be implemented as software, such as by an application program executing within the computer system 200. In particular, the steps of method of photographic data management are effected by instructions in the software that are carried out by the computer. The instructions may be formed as one or more code modules, each for performing one or more particular tasks. The software may also be divided into two separate parts, in which a first part performs the photographic data management methods and a second part manages a user interface between the first part and the user. The software may be stored in a computer readable medium, including the storage devices described below, for example. The software is loaded into the computer from the computer readable medium, and then executed by the computer. A computer readable medium having such software or computer program recorded on it is a computer program product. The use of the computer program product in the computer preferably effects an advantageous apparatus for photographic data management.

The computer system 200 comprises a computer module 201, input devices such as a keyboard 202 and mouse 203, output devices including a printer 215 and a display device 214. A Modulator-Demodulator (Modem) transceiver device 216 is used by the computer module 201 for communicating to and from a communications network 220, for example connectable via a telephone line 221 or other functional medium. The modem 216 can be used to obtain access to the Internet, and other network systems, such as a Local Area Network (LAN) or a Wide Area Network (WAN), and which can operate as a source of digital photographs. A further input device is seen as a digital camera 230 which connects to the computer module 201 via a connection 235, which is typically a Universal Serial Bus (USB) connection.

The computer module 201 typically includes at least one processor unit 205, a memory unit 206, for example formed from semiconductor random access memory (RAM) and read only memory (ROM), input/output (I/O) interfaces including a audio-video interface 207, and an I/O interface 213 for the keyboard 202 and mouse 203 and optionally a joystick (not illustrated), and an interface 208 for the modem 216. The audio-video interface 207 supplies video image signals to the display 214 and audio output signals to loud speakers 217. A 3D graphics accelerator card 250 is included as part of the interface 207 to assist in the processing and fast rendering of 3D graphical images. A storage device 209 is provided and typically includes a hard disk drive 210 and a floppy disk drive 211. A magnetic tape drive (not illustrated) may also be used. A CD-ROM drive 212 is typically provided as a non-volatile source of data. The components 205 to 213 of the computer module 201, typically communicate via an interconnected bus 204 and in a manner which results in a conventional mode of operation of the computer system 200 known to those in the relevant art. Examples of computers on which the described arrangements can be practised include IBM-PC's and compatibles, Sun Sparcstations or like computer systems evolved therefrom.

Typically, the application program is resident on the hard disk drive 210 and read and controlled in its execution by the processor 205. Intermediate storage of the program and any data fetched from the network 220 may be accomplished using the semiconductor memory 206, possibly in concert with the hard disk drive 210. In some instances, the application program may be supplied to the user encoded on a CD-ROM or floppy disk and read via the corresponding drive 212 or 211, or alternatively may be read by the user from the network 220 via the modem device 216. Still further, the software can also be loaded into the computer system 200 from other computer readable media. The term “computer readable medium” as used herein refers to any storage or transmission medium that participates in providing instructions and/or data to the computer system 200 for execution and/or processing. Examples of storage media include floppy disks, magnetic tape, CD-ROM, a hard disk drive, a ROM or integrated circuit, a magneto-optical disk, or a computer readable card such as a PCMCIA card and the like, whether or not such devices are internal or external of the computer module 201. Examples of transmission media include radio or infra-red transmission channels as well as a network connection to another computer or networked device, and the Internet or Intranets including e-mail transmissions and information recorded on websites and the like.

Where appropriate or desirable, parts of the described methods of photographic data management may be implemented in dedicated hardware such as one or more integrated circuits performing the functions or sub functions of data management Such dedicated hardware may include graphic processors, digital signal processors, or one or more microprocessors and associated memories.

FIG. 2B illustrates a functional relationship between the salient components of the system 200 for photograph database management. The digital camera 230 provides a source of digital photographs that are loaded 252 to the hard disk 210 of the computer 201 via the USB cable connection 235. During manipulation of the computer 201, for example via an operating system thereof, a photographic database is loaded 254 from the hard disk 210 to the main memory 206. Manipulation of the database may cause information to be added 258 to the database and retrieved 256 from the database. During display of the database upon the video display device 214, render instructions 260 are generated by the processor 205 and passed to the graphics card 250 for rendering and output. Such rendering may use texture information 262 that may be loaded from the hard drive 210 via the processor 205 and sent to the graphics card 250.

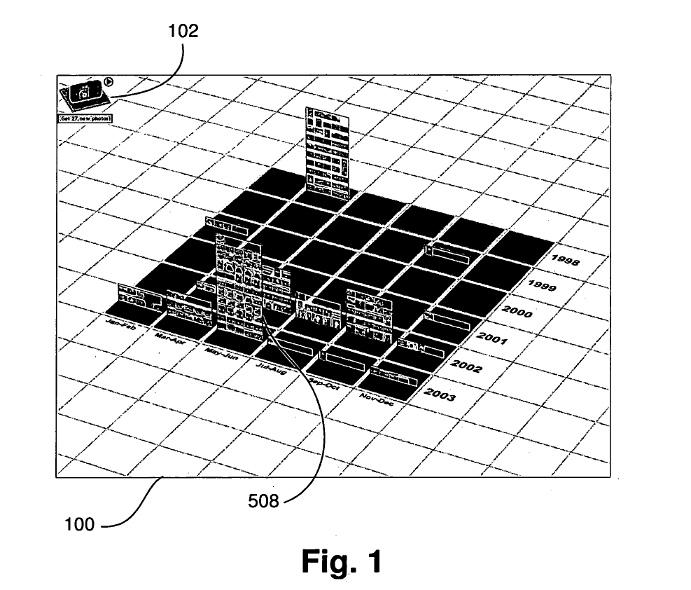

The presently disclosed arrangement provides a graphical user interface (GUI) for the presentation, selection and manipulation of a database of images. FIG. 1 shows typical window display according to the present disclosure as might be seen upon the display 214 for a collection of 196 JPEG images, sorted by year and month, and presented in the manner to now be described.

The application program that implements the GUI is formed by a event loop method 300, shown in FIG. 3, which continually polls for user events (in steps 320-330) and updates the screen display 214 on every loop (defined by rendering at step 335). The GUI program is capable of responding to user actions such as requesting photographs to be fetched from the camera 230, quitting the GUI program, or navigating around the view formed on the display 214 by means of clicking the mouse 203.

The GUI program maintains a database 270, seen in FIG. 2C which, consequential to program start-up at step 301 in FIG. 3, is loaded at step 305 from the hard disk drive 210 to the memory 206, this being represented by the functional process 254 of FIG. 2B. The database 270 contains at least one table 272 whose primary role is to maintain references to media files, and is henceforth called “the reference table 272”. Media in this regard includes, but is not limited to, digital photographs and digital video, as well as meta-data for these media files.

The reference table 272 of the database 270, as illustrated in FIG. 2C, typically has one media file reference per row (274-278) and sufficient other fields per row to store at least the following meta-data for the media file:
(i) photograph capture date,
(ii) the date that the photograph was added to the database,
(iii) the type of the media (photo, movie, other),
(iv) the number of times the user has accessed the media through the GUI program, and
(v) other EXIF or IPTC standard meta-data information.

The information in the reference table 272 establishes the window, graphics context and memory buffers required for drawing to the display 214 and to the graphics card 250, as well as appropriate drivers and dynamically linked libraries for image loading and communicating with other tools in components of the computer 301.

Media files may be passed to the GUI program in any of a number of ways. For example, a user may place the media in a directory on the hard-drive 210 which the GUI program scans periodically at step 315 looking for new files. Alternatively, by polling the user for certain events at step 320, the user can instruct the GUI program to add the media by dragging the files onto the GUI program or selecting the files in a file dialog presented by the GUI program. A further alternative, seen at step 325, is where the user instructs the GUI program to retrieve, depicted functionally at 252, the media from the digital camera 230 when such is connected to the computer 201. This process may be performed by an interface operated by the user operating the mouse 203 to select by clicking a camera icon 102, seen in the top left of FIG. 1. Photographs fetched in this way are stored, according to step 345, on the hard drive 210.

When a new media file is passed to the GUI program by step 315 or 325, step 340 subsequently operates to add a new row 280 to the reference table 272 and to insert a reference to the media file in one of the fields of the new row 280. This is illustrated functionally at 258 in FIG. 2B. Other fields of the new row 280 are populated with information derived from the media file, as noted above, which can all be extracted from the media file and added to the fields of the new row 280 at this time. If certain values are not present in the media file, those fields of the new row 280 may be initialised to default values.

If no new media is requested at step 325, step 330 follows to check whether or not the user has selected to quit the database management (GUI) program. If so, step 350 follows to perform a file clean-up and a closing of the GUI program. If not, step 355 follows to check for a click of the mouse 203 by the user. If a click is not detected, step 335 follows to render the scene. If a click is detected, step 360 follows to pick a new camera destination. The camera destination discussed in step 360 is a virtual camera position, being the virtual viewpoint within the OpenGL scene. In OpenGL, this is a conceptual combination of the GL_PROJECTION and GL_VIEWPORT matrices with the top level GL_MODELVIEW matrix. Frequently, these matrices are not manipulated directly but set using the function “gluLookAt” which allows the user to specify the “eye” coordinates and the “centre” coordinates (the target that the “eye” looks at) and a vector which specifies the “up” direction. It is also affected by the function “gluPerspective” which sets the field of view (both width and depth). It is to be noted that GLU functions, being functions whose names begin with “glu”, are not core OpenGL functions but are part of the OpenGL Utility Library. They exist to simplify some of the more tedious but commonly used mathematics and data processing aspects of OpenGL. Skilled persons who use OpenGL will have access to GLU.

In step 360, the “new camera destination” is the location to which the virtual camera will move after a zoom or other camera movement. The term “camera destination” is used because the camera's location is not set immediately. Instead, an endpoint is set, and each frame of rendering, the virtual camera is moved closer to its destination—thus a pan/zoom or other virtual camera movement is achieved. As such, if a click of the mouse 203 is detected, step 360 determines the object that the user has clicked on within the 3D scene and from this and the virtual camera's current location (fully zoomed out, partially zoomed in or fully zoomed in), determines a new endpoint for the camera's movement.

Step 335 follows from step 360.

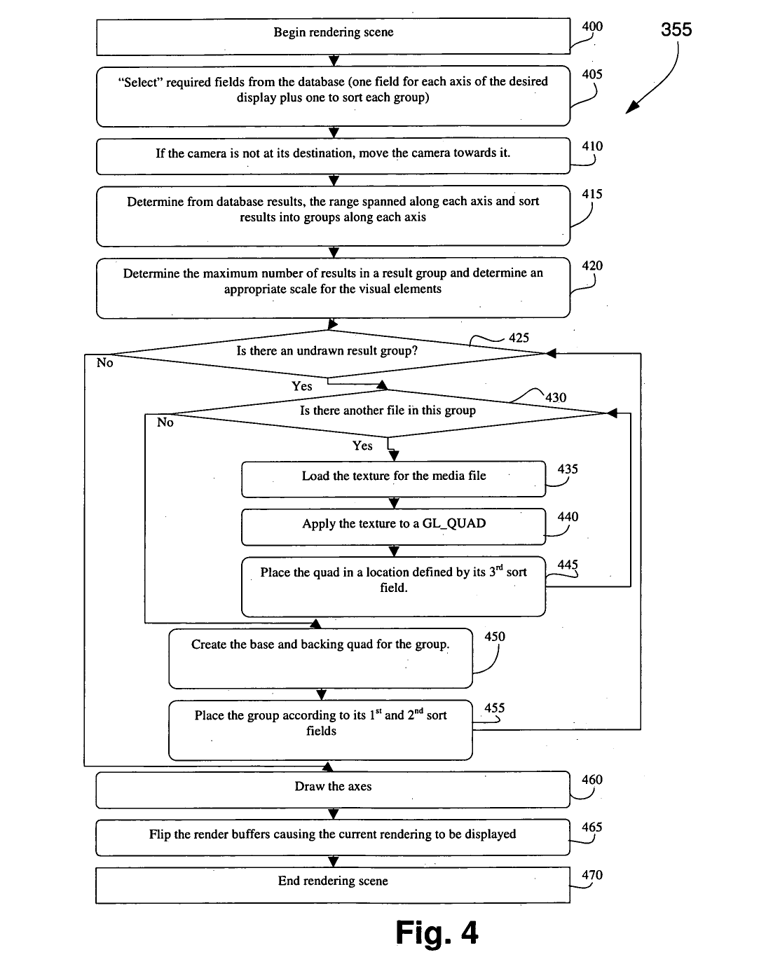

Once the database 270 contains all appropriate and available information, the GUI program then performs the task at step 355 of displaying the contained media to the user. Step 335 is shown in greater detail in FIG. 4, and has an entry step 400 which begins a rendering of the scene. The display of the information is constructed using calls to a 3D graphics language generally associated with and supported by the 3D graphics card 250 arranged within the computer 201. The two most common languages for this task are OpenGL, which is an industry standard 2D and 3D graphics application programming interface (API) (details of which may be obtained from www.opengl.org), and DirectX™ manufactured by Microsoft Corporation. Whilst both these languages are capable of constructing the scene formed by the GUI and may be used, the description that follows will rely upon the example afforded by OpenGL terminology.

Before the scene can be created, the information to be displayed must be retrieved from the database and before the information can be retrieved, the program must have at least one field for sorting the information. The field must be one of the fields available in the reference table 272 of the database 270. Example choices for fields by which to sort the information can include month and year and date, subject and location, keywords, as well as number of times viewed. If the user has not chosen a sort field or fields, default sort fields may be set as the month and year and date. The following description will consider information sorted by month and year and date although, as will be appreciated, any of the fields available may be used for sorting purposes. Step 405 operates to select the required field from the database 270, with each selected field representing an axis of the desired display.

With the sort fields chosen, step 405 also operates to build a query which can be sent to the database 405. If the database is one founded upon Structured Query Language (SQL), being a standard language for relational database management systems, (ie. an SQL database), the query might appear as follows:
SELECT media_reference, month, year, date FROM program_database ORDER BY year, month, date

This query will give the four fields, being media_reference, month, year and date, for every media file added to the database, which in this example is named program_database. The result will be sorted by year first, then within each year by month, then within each month by date. In this way, the information regarding the database 270 is retrieved from the memory 206, as functionally depicted at 256 in FIG. 2B.

Step 410 attends to adjustment of the position of the virtual camera as discussed above. Since the camera's specific location is not set (only an endpoint for the camera's movement is set), at some point it is necessary to actually animate the camera along the path towards its endpoint. Step 410 therefore attends to animation of the virtual camera along the viewpoint path.

Step 415 then operates to scan through the results and determine the months and years spanned by the results. The results are then clustered into groups based on their values along each of the two primary axes (year and month). From the groups formed, step 420 then operates to determine the largest number of media files that occur within a single month.

The rendering process 355 can now begin building the scene, in the present example, in OpenGL. It is assumed that a render context has been created and that the required OpenGL functions have been enabled at step 310, together with a light source and “camera” angle already being established, which establishes a 3D viewpoint for the 3D presentation of data. Graphical objects, by which a representation of the database 270 (ie. the “scene”) is to be viewed are then created by sending OpenGL shape instructions to the graphics card 250. This is depicted functionally in FIG. 2B by the processor 205 creating those instructions and sending them at 260 to the graphics card 250. These operations are depicted in the process 355 of FIG. 4 by step 425 which checks if there is an undrawn group from the search and, if so, by step 430 which checks if there is an undrawn file in that group.

If there is an undrawn file determined in step 430, step 435 follows to create an icon or thumbnail for each media file. The thumbnail for a photograph may simply be formed by an OpenGL quad (the default, four-sided drawing primitive in OpenGL), textured using the photograph and formed at step 440. Similarly, for a video file, a thumbnail may be formed by an OpenGL quad textured with a frame of the video. Textures are created on the graphics card 250 by transferring, as seen at 262 in FIG. 2B, a bitmap for the texture from the photograph or video's file on the hard drive 210.

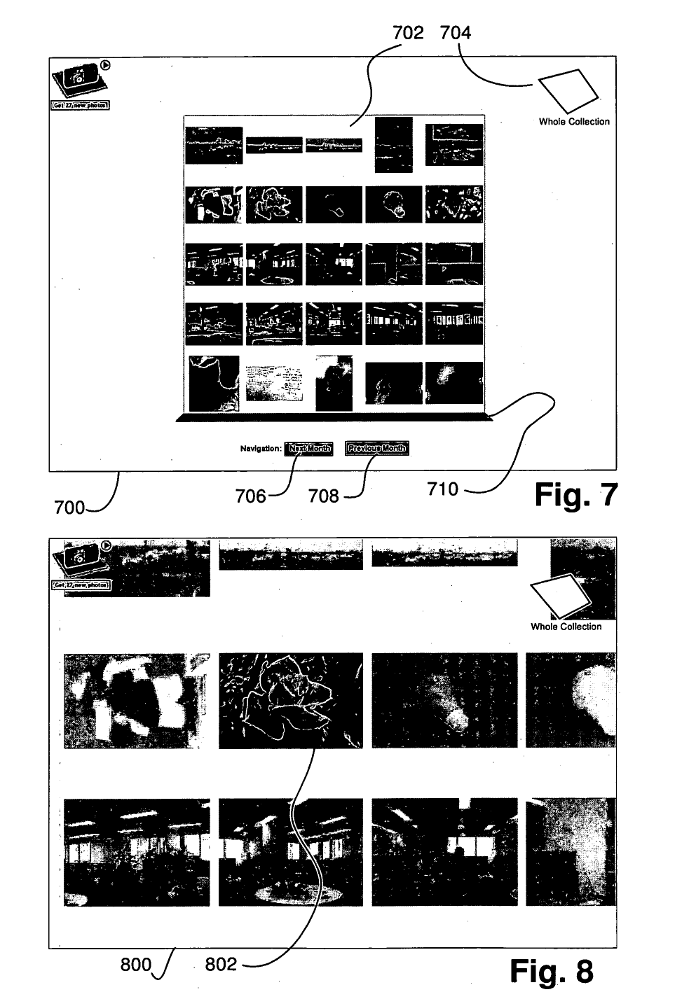

A “tower”, being a three-dimensional representation that contains the representations of the results from a single group, is then built for each group, according to step 445, by arranging the quads in a two-dimensional plane of rows and columns. Each quad is placed in a location defined by its third sort field, which defines a third dimension and provides meaning for the arrangement of quads within the tower. The number of columns should be chosen based on the previously calculated largest number of media files that occur within a single group. The number of columns will be the same for every group and should be chosen so that no group is too tall to fit within the GUI program's OpenGL window. To further give shape to the tower and ensure that it is not simply a two dimensional object, a square quad is drawn at the base of the tower, perpendicular to the plane of the other quads in the tower. An example of a single tower is shown in FIG. 7.

After step 445, operation of the GUI program returns to step 430 where a check is again made for another member of the group. When all members of the group have been processed, step 450 follows to create a base backing quad for the group. This is done by placing a flat coloured quad at the base of the group, perpendicular to the tower, but square with width and length equal to the width of the tower.

Step 455 places the towers (one for each group) to form an array upon a two dimensional plane. This plane is the same as the plane that the tower's base occupies. Step 455 returns to step 425 where the next group is processed 455. The collective result of these steps is to construct upon the two-dimensional plane, towers of thumbnail representations of images stored within the database 270.. The rows and columns of this array, in the present example, represent the month and year for the group, respectively. Had different search fields been used in the database query, the array rows and columns would reflect this. For example if only “number of times viewed” had been used in the query, there would only be one column with the rows of the column being the number of times the media files within the group had been viewed. The towers represented in the display of FIG. 1 are thus a collective representation of the media files each shown commencing and extending in a third dimension from the two-dimensional grid formed by the rows and columns. As a direct consequence, by being grounded to the grid, the “height” of each tower in the third dimension is indicative of the number of thumbnail images retained in that file directory of the hierarchical file structure being represented.

With the towers arrayed in the plane, step 460 follows to create text objects along the boundaries of the plane so as to label the axes, with the years and months in the present example.

Once fully arranged and built, the OpenGL scene can be rendered is step 465 by flipping the render buffers and by doing so, the result is displayed to the user upon the display 214.

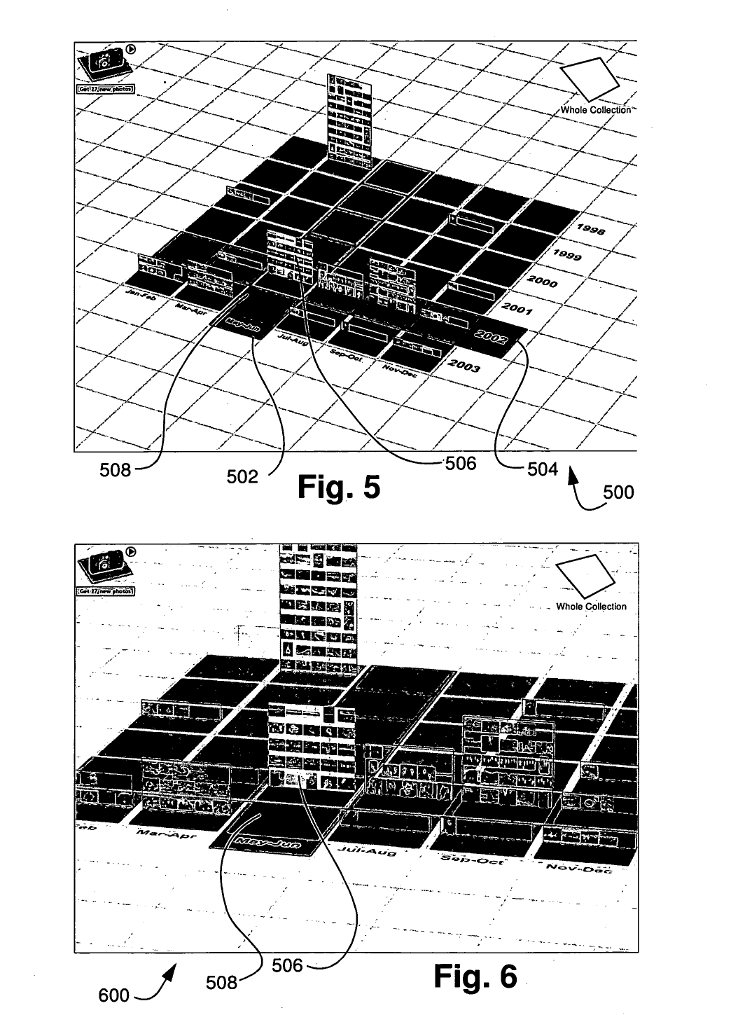

In FIG. 1, a GUI display 100 shows a media collection containing 196 photographs. The collection is viewed by pairs of months and year and, within each tower formed at each month pair/year intersection where a file exists, by filename. The 2D plane shows months from January to December and years from 1998 to 2003 and as such, spans the entire collection of media. Each photograph within the month and year for each square on the 2D plane is arranged into a perpendicular 2D grid of thumbnails. Since each of these 2D grids of thumbnails contains 5 columns of photographs, the height of the grid reflects the number of photographs for that year/month combination, rounded up to the nearest multiple of 5. These values may be selected to obtain a pleasing appearance. In FIG. 5, being a further representation of the media collection of FIG. 1, a cursor pointer associated with the mouse 203 is located over the intersection of the May-June column and the 2002 row, thereby causing that row and that column to highlight. The highlighting may be achieved using different colors for columns and rows, and different colors between rows and between columns, thereby aiding visual distinction of groups for user selection.

Advantages of this view when compared to the noted prior art representations include:
all photographs from a given month can be located quickly;
the display has a shape and pattern caused by towers of different height and gaps that allows users to quickly orient themselves within the view;
the 3D view is also visually appealing and is considered to have a specific appeal to the type of frequent computer user likely to take many digital photographs; and
the speed of modern 3D graphics cards, which may be used for the graphics card 250, allows speed of rendering and display that exceeds the performance of a traditional unaccelerated 2D display arrangement.

Variations on the display style of FIG. 1 include many different means of presenting the group at the intersection of a row and column. For example a rectangular prism may be used instead of a 2D grid of thumbnails, with the height of the prism being indicative of the number of media files in that group.

Another improvement which can be made is to cache processing that occurs in the main program loop 300 of FIG. 3. For example, it is unlikely that a user would desire creating textures for hundreds of media files every loop. These textures can be created once and left on the 3D graphics card 250 until they are no longer needed. Similarly, the database 270 need only to be queried when there is a change in the database 270. As such, results can simply be taken from the last query in all other cases.

Building the display is only one part of a media management program. The ability to select and view individual images is also required. For this, the GUI program requires a means of navigation. This is achieved by the user through interaction using the mouse 203 and the associated cursor pointer within the displayed GUI.

The first type of interaction the user can achieve is simply moving the mouse 203 to position the pointer over the display in the 3D view. The OpenGL function gluUnProject can be used to take the window (pixel) coordinates of the mouse, along with the GL_MODELVIEW_MATRIX, GL_VIEWPORT, GL_PROJECTION_MATRIX and the GL_DEPTH_COMPONENT of the pixel under the mouse to give the OpenGL coordinate of the point that the mouse is over. If it is ever determined that this OpenGL coordinate lies within the bounds of a valid tower within the scene, then when building the display axes at step 460, an extra quad may be added under the column and row of the tower.

The result of the above process is a track highlight, such as that shown in the GUI display 500 of FIG. 5. In that example, the track 502 representing the months May-June and track 504 representing the year 2002 have been highlighted, resulting in a highlighting of the tower 506 at the intersection thereof. The tower 506 shows a collection of thumbnail images.

The second type of interaction is a mouse click. When a click of a button formed on the mouse 203 is detected, the group associated with the click is selected. The grid coordinate as determined above is obtained and a new 3D camera viewing position is sought which places the camera viewpoint, and thus the user viewing the display 214, very close to the grid coordinate and directly facing the 2D plane of the group at that coordinate. The camera position is not set explicitly, but instead a destination is set so that at each render update step 410, the camera viewing position moves closer to this destination. This creates a smooth zoom-like effect which has two benefits. Firstly, the “zoom” is appealing and secondly the user never loses track of where they are or how they reached their current viewpoint.

Simultaneously, a destination camera position may be set. Further a destination alpha (opacity) value is preferably set to zero (ie, fully transparent) for all other groups at all other grid coordinates. In an alternative, the destination opacity may be set to zero, or close thereto, for those groups in the immediate vicinity of the selected group. This destination alpha is updated at the same time as the camera position is updated during each render of the “zoom”. The result is that, as the GUI display zooms into the grid coordinate at which the user has clicked, some or all other grid points fade away so that there is no occlusion of the selected group by other towers and no confusing peripheral elements.

FIG. 6 shows an exemplary 3D render frame 600 during the zoom transition to the tower 506. It will also be seen from FIGS. 5 and 6 that a further tower 508, at the intersection of May-June 2003, is transparently depicted to aid the highlighting of the tower 506. The further tower 508 is shown opaque in FIG. 1. The “vicinity” in which opacity is altered may be varied according to the size of towers surrounding that group which is selected and the extent of possible occlusion. An immediate vicinity in the example of FIGS. 5 and 6 may therefore include those eight groups that are immediately adjacent the selected group 506.

In a further alternative, without a need to click the mouse 203, as the mouse 203 is moved over the display 500, groups and towers other than that over which the mouse cursor currently lies, may be made wholly or partly transparent, to thereby afford the user of immediate visual feedback of that group or tower immediately available for selection.

From the frame 600 of FIG. 6, in comparison with the view 500 of FIG. 5, it will be appreciated that the camera viewpoint is swinging around to a position perpendicular to the plane of the selected group and that the viewpoint is also zooming-in so that the selected group begins to fill the display screen 214. All other non-selected groups are in the process of fading away.

FIG. 7 shows a view 700 including 25 photographs comprising the thumbnails of the tower 506 from the final position of the camera viewpoint after the transition from FIG. 5 via that of FIG. 6. The view 700 is analogous to a typical “grid of thumbnails” view in other photograph or video clip management software. Whilst the view of FIG. 7 is effectively a “2D elevation” view of the 3D tower 506, the tile 702 that the group rests upon reminds the user that the view 700 remains one part of a 3D environment, adding both context and consistency at the same time.

The re-positioning of the viewpoint in the fashion described above and illustrated in FIGS. 5 to 7 may be performed by using the OpenGL function gluLookAt( ) or by setting the GL_PROJECTION and GL_MODELVIEW matrices directly.

In certain implementations, not shown in the drawings, the same types of selection, movement and other actions that are typical under this type of software (eg. OpenGL) can be performed. This includes menu items to perform a slideshow on the currently displayed images or selecting some images and sending them to an external program for editing or selecting some images and emailing them.

Once the camera has reached the viewpoint shown in FIG. 7, three new mouse actions are possible, those being:
(i) the user can click on an image in the group;
(ii) the user can click on one of the navigation buttons; or
(iii) the user can click on the “Whole Collection” 704 in the top right of the window 700.

If the user clicks on the “Whole Collection” 704 in the top right of FIG. 7, the reverse of all camera and alpha transitions between FIG. 5 and FIG. 7 are applied. The result is that the camera is moved back to its starting position and all grid locations become visible again.

If the user clicks on one of the navigation buttons (in FIG. 7 they are labelled “Next Month” 706 and “Previous Month” 708), the camera viewpoint destination is set to the appropriate point for the next or previous grid coordinate, as though the user had clicked on the next or previous month from the “Whole Collection” view (ie. FIG. 5). The destination group has its destination alpha set to one (fully opaque) and the currently displayed group has its destination alpha set to zero. The result is that the camera viewpoint moves either forwards to the next group or backwards to the previous group, and that the current group fades to fully transparent while the destination group becomes fully opaque.

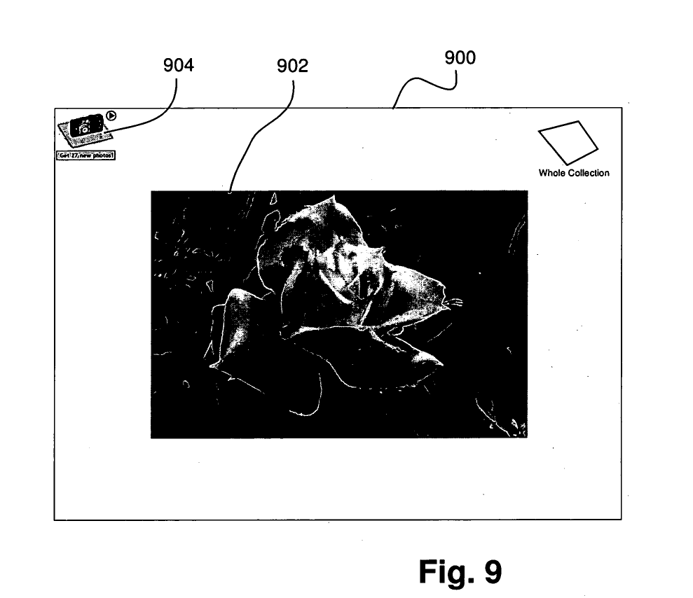

If the user clicks on one of the photographs in FIG. 7, the thumbnail under the mouse pointer is determined by obtaining the OpenGL coordinates of the point under the mouse and determining if this point is within the bounds of one of the thumbnail representations. The OpenGL function gluUnProject can be used to take the window (pixel) coordinates of the mouse, along with the GL_MODELVIEW_MATRIX, GL_VIEWPORT, GL_PROJECTION_MATRIX and the GL_DEPTH_COMPONENT of the pixel under the mouse to give the OpenGL coordinate of the point that the mouse is over. By doing this, and by further rounding the result to the nearest thumbnail point, the coordinates of the centre of the thumbnail selected are determined. The camera viewpoint destination is then set to a location close enough to the thumbnail in order for the thumbnail to fill the screen, with the thumbnail centred in the camera viewpoint. Further the destination alpha of all thumbnails in the group (except the selected thumbnail) and the group itself are set to zero. The result is that the camera viewpoint zooms in to the thumbnail while everything else fades out of view. FIG. 8 shows a render frame 800 during this transition with the target photograph 802 getting larger in the view as the camera moves into it and the other photographs fading to blank. FIG. 9 shows the endpoint of this transition, with the zoom complete providing a view 900 including only the selected photograph 902.

From FIG. 9, any mouse click except a mouse click on the camera 904 (top left) or the “Whole Collection” 906 (top right) results in a reverse transition back to that of FIG. 7. Clicking the “Whole Collection” 906 results in a transition all the way back to FIG. 5 in one step. Clicking the camera 904, as at any point during the execution of the GUI program, fetches any new photographs from the camera 230 according to step 345.

In another implementation, not shown in FIG. 9, this closest view allows the user to perform edit and modification behaviours typical to photograph or video clip management applications. These behaviours include adding keyword metadata or adjusting image brightness and contrast or sending the media file to an external application for viewing and editing. The ability to move to the next or previous photograph in the group may also be made available.

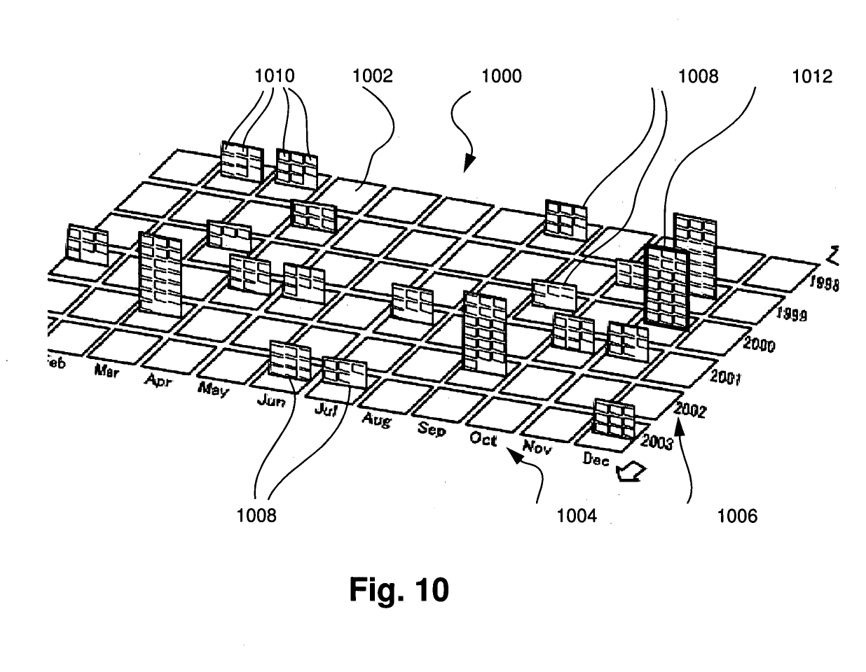

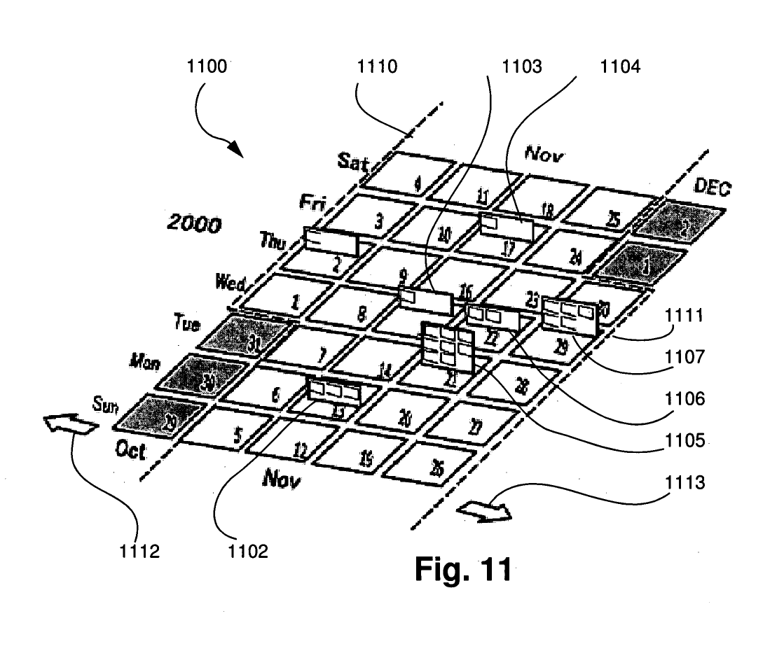

FIGS. 10 and 11 illustrate a further alternative for photo album navigation, which build upon the structures shown in FIGS. 5 and 6. FIG. 10 shows a three-dimensional representation 1000 formed by a two-dimensional grid 1002 of months 1004 in one dimension and years 1006 in the other. The months and years represent ranges of dates respectively by which a hierarchical file database may be sorted. The representation 1000 is that of a hierarchical file directory structure of photographs arranged according to date of image capture, for example. At various ones of the grid coordinates, towers 1008 of thumbnail images 1010 are represented extending in a third dimension from the plane of the grid 1002. Movement of the mouse 203 as before results in corresponding movement of a mouse cursor across the GUI of which the representation 1000 forms a part. In this implementation, where the user wishes to review in detail the images in any one tower, a mouse click on that tower, for example the tower 1012 at Nov-2000, results in the GUI altering to the representation 1100 shown in FIG. 11. As is seen, the transition between FIGS. 10 and 11 results in a hierarchical change in representation for months and years, to days within the selected month. Further as seen, the single tower group 1012 of FIG. 10 is represented in FIG. 11 by seven towers 1101-1107 each of which possessing at least one thumbnail image captured on the corresponding day. Further, whilst the 2D plane in FIG. 10 is sorted according to two fields (month, year), the 3D plane of FIG. 11 may be considered sorted according to one field, being date.

From FIG. 11, it is noted that the representation 1100 is laid out akin to a calendar with the month (November), being shown arranged in its appropriate weeks. The weeks provide appropriate ranges of a second field by which the files of the tower group 1012 may be sorted. A pair of lines 1110 and 1111 delineate the month of November from adjacent months October and December respectively, with the days of those months that fill the grid in the representation 1100 being shaded a different color so as to clearly distinguish them from the selected month. A pair of arrow icons 1112 and 1113 are also provided and which are selectable by operation of the mouse 203 to shift or scroll the representation 1100 into the adjacent month of October or December respectively. Thus the representation of FIG. 11 affords a detailed representation of a lower level of the hierarchical file structure, different from that of FIG. 10, but nevertheless in a consistent and hierarchically interpretable manner.

The navigation of the three dimensional view described above is quite distinct from typical “virtual reality” methods or immersive forms of interaction as known in the prior art. While the camera viewpoint does move in the 3D model, all visible elements remain in view at any given time. The advantages of this include:
the user does not need to turn their head (ie. adjust the camera viewpoint) to see what is behind them;
access to a global view of everything (the “Whole Collection”) is available in one click of the mouse 203;
navigation operates at the same point and in a similar click style that user are familiar with from two dimensional GUIs;
slow, walking-style navigation around a 3D environment is not required—instead, quick zooming transitions occur with a single mouse click;
navigation is simpler than immersive environments because only two types of action are required: zoom in or zoom out, with navigation between groups (“Next Month” and “Previous Month”) being strictly optional and not required to access any part of the collection;
the tile is still visible in the intermediary hierarchy level (the dark trapezoid 710 at the base of the group in FIG. 7) reminding the user that they are at one “square” of the “Whole Collection” view.

The GUI program described above provides a method of viewing thumbnail representations of media files from a database in three dimensions, where the thumbnails are sorted along two or more fields of the database and grouped within a range along both fields, with the groups being arranged according to their values along the two sort fields. This results in an ordered presentation of the information in a fashion consistent with methods of interpretation typically employed by users. This arises from the use of sort terms and the familiarity of users in identifying a 2D intersection of terms and then assessing the information at the intersection, which may be a single photograph or a collection of photographs. The GUI program also provides a means of navigating a set of groups displayed in three dimensions.

Although the present description is centred upon media files having image (eg. thumbnail) representations, the principles disclosed herein may be readily applied to databases that utilize any one or more of a range of file types. For example, operating systems such as Windows™ afford general file searching functionality which may be limited by date, date range, file name and file type for example. The search result may then be sorted based upon a file attribute such as name, size, type or date. Consequently, multiple searching dimensions can be applied across a general database of files. These may then be used to generate a 3D view similar to those of FIGS. 1, and 5-9. Further, the present disclosure is also applicable to broader collections of data that may not be file-structured. Such include arrangements where a number of data objects are arranged in a collection that is not file-based and not a database.

### INDUSTRIAL APPLICABILITY

The arrangements described are applicable to the computer and data processing industries and particularly in respect of management of large numbers of visual media files.

The foregoing describes only some embodiments of the present invention, and modifications and/or changes can be made thereto without departing from the scope and spirit of the invention, the embodiments being illustrative and not restrictive.

1. A method of viewing a collection of data objects, said method comprising the steps of:
(a) sorting said collection according to at least two fields associated with said data objects;
(b) arranging said data objects within a range along said at least two fields into groups; and
(c) forming a three dimensional presentation of said collection having two of said dimensions formed by two of said at least two fields and a third dimension incorporating a representation of each said data object in the corresponding said group.

2. A method according to claim I wherein the third dimension comprises a collective representation of said data objects for a group commencing and extending from a plane established by said two dimensions.

3. A method according to claim 1 further comprising the steps of:
(d) detecting a user selection of one said group; and
(e) identifying a range associated with each of said two fields and intersecting at the selected group; and
(f) modifying a representation of said identified ranges in said three dimensional presentation to be distinct from a representation of the other non-identified ranges.

4. A method according to claim 1 further comprising the steps of:
(g) detecting movement of a cursor at least over a representation of one said group in said three dimensional presentation;
(h) modifying a representation of at least one other said group in said three dimensional presentation to be at least substantially transparent to thereby prevent occlusion of said one group.

5. A method according to claim 4 wherein step (h) comprises modifying representations of others of said groups located in said three dimensional presentation within a predetermined vicinity of said one group.

6. A method according to claim 4 wherein step (g) comprises detecting a user selection of said one group.

7. A method according to claim 1 wherein different ranges in each of said two dimensions are distinguished by different colors.

8. A method according to claim 1 further comprising the steps of:
(i) detecting a user selection of one said group defined by corresponding ranges of said two fields;
(j) sorting said selected group according to at least one further field associated with said files of said selected group
(k) arranging said data objects of said selected group within a range along said at least one further field into sub-groups; and
(l) forming a three dimensional presentation of said selected group having at least one dimension of a two dimensional plane formed by ranges of said one further field, and a third dimension incorporating a representation of each said data object in the corresponding said sub-group.

9. A method according to claim 8 wherein said two dimensional plane is formed by ranges of two said further fields.

10. A method according to claim 1 wherein said data objects represented in each said group are sorted according to one of said fields not being one of said two fields.

11. A method according to claim 1 wherein said dimensions of said two fields are divided into corresponding ones of said ranges to thereby form a two-dimensional array of display locations at which the corresponding said group is displayable in said third dimension.

12. A method according to claim 1 wherein when said data object comprises a visual media file, said representation comprises a corresponding thumbnail representation thereof.

13. A method according to claim 1 wherein said fields are selected from the group consisting of:
(i) a day of creation of said data object;
(ii) a month of creation of said data object;
(iii) a year of creation of said data object;
(iv) a date of creation of said data object;
(v) a size of said data object;
(vi) a name of said data object;
(vii) a data type of said data object;
(viii) a date of addition of said data object to said collection;
(ix) a number of times said data object has been accessed; and
(x) a user specific data associated with said data object.

14. A method according to claim 1 wherein said presentation forms part of a graphical user interface having an associated pointing device, said method further comprising the steps of:
(d) detecting a locating of said pointing device coincident with one of said groups;
(e) altering said three dimensional presentation by increasing an opacity of said one group and/or increasing a transparency of the others of said groups.

15. A method according to claim 1 wherein said data objects comprise data files.

16. A method according to claim 1 wherein said collection comprises a database.

17. A method of navigating a collection of data objects, said method comprising the steps of:
(a) generating an initial three-dimensional view of said collection, said generating comprising:
(aa) sorting said collection according to at least two fields associated with said data obejcts;
(ab) identifying those ones of said data objects having intersecting ranges of values of said at least two fields according to said sorting and arranging said identified data objects within each said range into a corresponding group of said data objects;
(ac) forming a three dimensional presentation of said collection having two of said dimensions formed by two of said at least two fields and a third dimension incorporating a representation of each said data object in the corresponding said group, said three dimensional presentation having a initial viewpoint;
(b) detecting a selection of one of said groups and altering said initial view of said collection to a group view, said group view comprising a two dimensional view of the third dimension of said group from said initial view and being taken from a corresponding group viewpoint; and
(c) detecting a selection of a representation of one said data object from said group view and altering said group view to provide a two dimensional view of a representation of said selected data object from a data object viewpoint.

18. A method according to claim 17 wherein said altering said initial view of step (b) comprises the sub-steps of:
(ba) identifying a (first) transition path in three dimensional space from said initial viewpoint to said group viewpoint;
(bb) identifying at least one intermediate viewpoint along said first transition path; and
(bc) at each intermediate viewpoint, in turn from said initial viewpoint to said group viewpoint, forming a corresponding three dimensional representation of said database.

19. A method according to claim 18 wherein step (bc) comprises, at each said intermediate view point, progressively increasing a transparency of those non-selected ones of said groups whilst at least maintaining an opacity of said selected group.

20. A method according to claim 17 wherein said altering said group view of step (c) comprises the sub-steps of:
(ca) identifying a (second) transition path in three dimensional space from said group viewpoint to said data object viewpoint;
(cb) identifying at least one transitional viewpoint along said second transition path; and
(cc) at each transitional viewpoint, in turn from said group viewpoint to said data object viewpoint, forming a corresponding representation of said data object.

21. A method according to claim 20 wherein step (cc) comprises, at each said transitional view point, progressively increasing a transparency of those non-selected ones of said data objects from said selected group whilst at least maintaining an opacity of said selected data object.

22. A method according to claim 17 wherein said method steps are reversible to traverse from said data object view to said group view, and from said group view to said initial view.

23. A method according to claim 17 wherein said data objects comprise visual media files and said representations comprise corresponding thumbnail representations of said files.

24. A computer readable medium having a computer program recorded thereon and adapted to make a computer execute a procedure for viewing a database including files of at least one file type, said program comprising:
code for sorting said database according to at least two fields associated with said files;
code for arranging said files within a range along said at least two fields into groups; and
code for forming a three dimensional presentation of said database having two of said dimensions formed by two of said at least two fields and a third dimension incorporating a representation of each said file in the corresponding said group.

25. Computer apparatus adapted for viewing a database including files of at least one file type, said apparatus comprising:
means for sorting said database according to at least two fields associated with said files;
means for arranging said files within a range along said at least two fields into groups; and
means for forming a three dimensional presentation of said database having two of said dimensions formed by two of said at least two fields and a third dimension incorporating a representation of each said file in the corresponding said group.

26. A graphical user interface for providing a three dimensional representation of a database of files of at least one file type, said interface comprising:
a two dimensional representation formed from a sorting of at least two fields associated with said files, said representation including ranges along each of said two dimensions and by which said files are grouped at intersections thereof; and
a third dimensional representation commencing at and extending from said two dimensions representation and incorporating a representation of each said group of files.
